(19) United States
(12) Patent Application Publication
(10) Pub. No.: US 2020/0053852 A1
(43) Pub. Date: Feb. 13, 2020

(54) LIGHT EMITTING DEVICE

(71) Applicant: ZIGEN LIGHTING SOLUTION Co., Ltd., Hiroshima (JP)

(72) Inventor: Tomokazu Nada, Hiroshima (JP)

(21) Appl. No.: 16/600,493

(22) Filed: Oct. 12, 2019

Related U.S. Application Data
(63) Continuation of application No. PCT/JP2018/010354, filed on Mar. 15, 2018.

(30) Foreign Application Priority Data
Apr. 12, 2017 (JP) 2017078631
Mar. 9, 2018 (JP) 2018043662

(51) Int. Cl. H05B 33/08; H01L 25/16

(52) U.S. Cl. CPC H05B 33/0857; H05B 33/083; H01L 25/167

(57) ABSTRACT

A light emitting device is provided with a first LED element array and a second LED element array, each of which has one or more LED elements. The first LED element array and the second LED element array are connected in series with each other. At least one of which connected in parallel with a bypass circuit that comprises a resistor and a diode. A threshold voltage of the LED element array connected in parallel with the bypass circuit is higher than a threshold voltage of the diode, and an emission color by emission of the first LED element array is different from an emission color of light by the emission of the second LED element array.

This application claims priority under 35 U.S.C. § 120 to, and is a continuation of, co-pending International Application PCT/JP2018/010354, filed Mar. 15, 2018 and designating the US, which claims priority to Japanese Application 2017-078631, filed Apr. 12, 2017, and Japanese Application 2018-043662, filed Mar. 9, 2018, such Japanese Applications also being claimed priority to under 35 U.S.C. § 119. These Japanese and International applications are incorporated by reference herein in their entireties.

### BACKGROUND

### Field

The present invention relates to a light emitting device and a lighting apparatus and, in particular, to a light emitting device and a lighting apparatus which change light emission color according to input current.

Light emitting devices that use light emitting diodes (LEDs) convert applied power directly to light, achieving very high light emission efficiency compared to conventional light sources, and have been used in many lighting fixtures in recent years.

With traditional light sources, especially incandescent or halogen lamps, as input power decreases, color temperature of emitted white light decreases and yellow and redness increase. People feel this color change comfortable and natural. Further, since the incandescent lamp and halogen lamp are a single light source, a single light source that changes emission color is desirable for a light emitting device that uses LED.

On the other hand, a light emitting device using LED generally exhibits a substantially constant light emission color with respect to input power. Thus, in order to adjust a light emission color of a light emitting device using LED, it is usually necessary to operate LEDs having different luminescent color in independent circuits. As a method a desired emission color from a lighting device, it is generally known to control current to individual circuits having LEDs of different emission colors by a processor or the like.

However, there is disadvantage that a lighting system becomes complicated and expensive in the methods of driving LEDs of different luminescent colors by independent circuits, due to requirements such as an input signal to a processor, a current control to a plurality of circuits in accordance with an emission color point and a feedback control by detecting light emission. In addition, because it consists of independent circuits, two or more light sources are typically included.

Consequently, as disclosed in Japanese Unexamined Patent Application Publication No. 2015-201614 (PTL 1), a light emitting device of chip-on-board (COB) type with a single light emitting portion which realizes light-emission color change similar as a halogen lamp just by adjusting a magnitude of an input current has been proposed.

In the light emitting device described in PTL 1, light emitting regions are formed for each LED element array having different threshold voltages in a single light emitting portion, and the LED element array with a low threshold voltage has a resistance in series. The LED element arrays are arranged in parallel to realize an emission color change according to the magnitude of the current. For example, when the color temperature emitted from the light emitting region having the LED element array with the low threshold voltage is set 2000 K and the color temperature emitted from the light emitting region having the LED element array with the high threshold voltage is set 3000K, the light emitting device achieves a favorable light emission color change like the color change of conventional incandescent light bulbs by dimming.

### SUMMARY

### Technical Problem

However, for the light emitting device described in PTL 1, since the LED element arrays under different emission regions are necessary to be connected in parallel inside the light emitting portion, when the LED element array is short such as less than 3 series, the light emitting portion becomes shorter in series direction of the LED element arrays and becomes longer in parallel direction of the LED element arrays, thus it is difficult to make a light emitting portion of a circular shape which is desirable for COB. Also, when the difference in series number of the LED element arrays is small, it is difficult to make more desirable emission color change. In order to increase the driving voltage of the light emitting device, it is necessary to increase the series number of each LED element array arranged in parallel, but it is difficult to form longer LED element arrays in parallel in a limited mounting area. Accordingly, the range of driving voltage is limited in an actual light emitting device.

Further, since it is necessary to connect the LED element arrays of a different light emitting regions in parallel in the light emitting portion, it is difficult to approach a point light source which is ideal as a single light source. Thus, for example, it is difficult to realize a surface mount type package or the like which has a limited light emitting area.

Also, the difference of the threshold voltage between the LED element arrays to create light emission color change results the difference in driving voltage of the low current region and the rated current region. Correspondingly, it is necessary to use a variable current power supply having a wide output voltage range, and there are limited commercially available power supplies or the cost for adapting the power supply is increased. In addition, in the further lower output region, the driving voltage further decreases, and the variable current power source may not be able to cope with continuous reduction in output power and may be turned off. This can be a reason of unstable light output when light reduction.

In order to reduce the driving voltage difference between the low current region and the rated current region, when setting the threshold voltage difference between the LED element arrays to be small, the resistance connected to the LED element array of lower voltage must be small. This makes difficult to achieve originally targeted emission color change, since the current limit functionality of the resistance is impaired and the ratio of the current to the LED element array of higher voltage with respect to the current to the LED element array of lower voltage becomes smaller at the rated current.

The present invention, made in view of the above problems, has an object to provide a light emitting device which light emission color changes depending on the magnitude of an input current having a wider driving voltage, a reduced area of the light emitting portion and smaller driving voltage difference between the low current region and the rated current region.

### Solution

In order to attain the above object, a light emitting device of the present invention comprises: a first LED element array and a second LED element array, each of which has one or more LED elements, wherein the first LED element array and the second LED element array are connected in series, at least one of which is connected in parallel with a bypass circuit having a resistor and a diode in series, a threshold voltage of the LED element array connected in parallel with the bypass circuit is higher than a threshold voltage of the diode, and an emission color by emission of the first LED element array is different from an emission color by the emission of the second LED element array.

In one aspect of the light emitting device of the present invention, the first LED element array, the second LED element array and the bypass circuit are formed on a single substrate.

In one aspect of the light emitting device of the present invention, a difference of color temperature between the emission color generated by emission of the first LED element array and the emission color generated by emission of the second LED element array is equal to or larger than 1000 K.

In one aspect of the light emitting device of the present invention, the diode is a Zener diode.

In one aspect of the light emitting device of the present invention, the light emitting region which emits light of each LED device array is formed to have two or more axes of symmetry passing through the emission center from top view.

The threshold voltage is the voltage where the current rapidly increase with respect to the forward voltage applied to a diode such as an LED, and the threshold voltage of the LED element array is the sum of the threshold voltage of the LED elements arranged in series. In general, an LED starts emit light by a current flow when the voltage gets higher than the threshold voltage. The threshold voltage of the diode in the bypass circuit is the sum of the respective threshold voltages, when a plurality of diodes is connected in series. Further, the breakdown voltage of a Zener diode connected in reverse direction is the voltage at which the current rapidly increases and consists part of the threshold voltage of the bypass circuit also.

According to the present invention, it is able to provide a light emitting device which light emission color changes depending on the magnitude of an input current having a wider driving voltage, a reduced area of the light emitting portion and smaller driving voltage difference between the low current region and the rated current region.

### BRIEF DESCRIPTION OF DRAWINGS

FIG. 1 is a wiring diagram of a light emitting device according to a first embodiment of the present invention.

FIG. 2 is a plan view of FIG. 1.

FIG. 3 is a wiring diagram of a light emitting device according to a variation of the first embodiment of the present invention.

FIG. 4 is a wiring diagram of a light emitting device by a prior art.

FIG. 5 is a plan view of FIG. 4.

FIG. 6 is a wiring diagram of a light emitting device according to a second embodiment of the present invention.

FIG. 7 is a plan view of FIG. 6.

FIG. 8 is a wiring diagram of a light emitting device according to a third embodiment of the present invention.

FIG. 9 is a plan view of FIG. 8,

FIG. 10 is a wiring diagram of a light emitting device according to a fourth embodiment of the present invention.

FIG. 11 is a plan view of FIG. 10.

FIG. 12 is an A-A sectional view of a light emitting device of FIG. 10.

FIG. 13 is a wiring diagram of a light emitting device according to a fifth embodiment of the present invention.

FIG. 14 is a wiring diagram of a light emitting device according to a variation of the fifth embodiment of the present invention.

FIG. 15 is a graph showing a relationship between the relative luminous flux of the light emission and the color temperature of the emission color from the light emitting device of the present invention.

FIG. 16 is a graph showing a relationship between the input current and the driving voltage of the light emitting device according to the present invention and the prior art.

### DETAILED DESCRIPTION

Hereinafter will be described with reference to the accompanying drawings of a light emitting device of the present invention. In the drawings of the present invention, the same reference numerals are used to represent the same or corresponding portions. Also, in the following description, the same names and signs, in principle, show the same or equivalent members and a detailed description thereof will be omitted appropriately. Further, dimensional relationships such as length, width, thickness and depth are appropriately changed for clarification and simplification of the drawings, and do not represent actual dimensional relationships.

### Embodiment 1

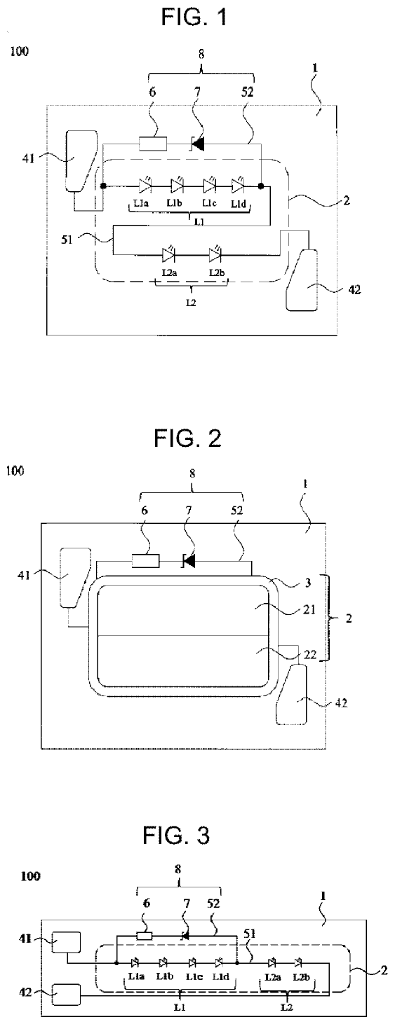

As shown in a wiring diagram of a light emitting device 100 of FIG. 1, the light emitting device 100 is a COB type and a single light emitting portion 2 is formed on a substrate 1. An LED element array L1 by electrically connected LED elements L1a˜L1d and an LED element array L2 by electrically connected LED elements L2a and L2b are formed inside the light emitting portion 2. LED element arrays L1, L2 are connected in series between electrode lands 41, 42 by wiring 51. A bypass circuit 8, comprising a resistor 6, a Zener diode 7 and wiring 52 is connected in parallel with the LED element array L1.

As shown in a plan view of the light emitting device 100 of FIG. 2, the light emitting portion 2 has a resin dam 3 on the periphery, consists from a light emitting region 21 including the LED element array L1 and a light emitting region 22 including the LED element array L2, each covered with a translucent resin. The light emitting region 21 and the light emitting region 22 emits different luminous colors. Since the light emitting regions 21, 22 exist inside the light emitting portion 2, the emission color is able to vary as a single light source.

Incidentally, ‘A single light source’ is to mean that it is possible to design the lighting apparatus with a single light source, the light emitting regions 21, 22 in the light emitting portion 2 are not necessarily in contact with each other. The light emitting region 21 may be formed so as to surround a light emitting region 22. Furthermore, as shown in a variation example of FIG. 3, the light emitting portion may be a linear shape like a rectangular or a filament where the LED element arrays L1, L2 are connected in series and the light emitting regions 21, 22 are formed for each LED element array as described above.

A breakdown voltage of the Zener diode 7 of the bypass circuit 8 is lower than the threshold voltage of the LED element array L1 which connects with the bypass circuit 8 in parallel. When driving the light emitting device 100 at low current region, the input current does not flow through the LED element array L1 but flows through the bypass circuit 8 to the LED element array L2. Thus, at low current region, only the light emitting region 22 in the light emitting portion 2 emits light, and the light emitting device 100 emits emission color of the light emitting region 22.

When the current is increased from low current region, a driving voltage of the bypass circuit 8 increases by the resistance of the bypass circuit 8. When the driving voltage of the bypass circuit 8 exceeds the threshold voltage of the LED element array L1, the current starts to flow through the LED element array L1, and the light emitting region 21 as well as the light emitting region 22 emits light. When the current is further increased, the emission color of the light emitting device 100 gets closer to the light emission color of the light emitting region 21, as the current ratio flowing to the LED element array L1 gets higher relative to the current through bypass circuit 8.

For lighting applications, it is preferable that the emission color of the light emitting region 21 by emission of the LED element array L1 and the emission color of the light emitting region 22 by emission of the LED element array L2 are white light. And by over 1000K difference in color temperature, the light emitting device will realize an obvious color temperature change. More preferably, by setting the emission color of the light emitting region 22 to a color temperature lower than the light emission color of the light emitting region 21, the emission color from the light emitting device can be changed to warmer light when decreasing current.

For example, if the emission color of the light emitting region 22 is set to a color temperature of 2000K and the emission color of the light emitting region 21 is set to a color temperature of 3000K, the emission color of the light emitting device 100 emits the color of the light emitting region 22 in the low current region, and gets closer to a color temperature of 3000K by the mixed light from the light emitting region 21, 22 in the rated current region. Thus, the light emitting device with the color change such as a conventional incandescent bulb in accordance with the dimming can be realized.

As the emission intensity of the light emitting region 22 becomes higher in accordance with the current increase, the emission color of the light emitting region 21 is preferably higher than a color temperature 4000K to achieve a color temperature of 3000K from the light emitting device in the rated current region. With the difference in a color temperature of more than 2000K, which creates overlap of the different spectrum from each emission color, it is possible to obtain a high-quality light with a high color reproducibility.

### (Substrate)

In order to use the light from the LED elements effectively for the light emission from the light emitting device, a substrate 1 is preferably a material with high reflectivity and high heat radiation, and a ceramic substrate, an aluminum substrate or the like is used.

By mounting all necessary LED elements and components on the substrate 1, it is possible to provide a COB type light emitting device that is easy to handle.

Further, the substrate 1 is preferably flat in both upper and lower surfaces, to enhance productivity such as formation of circuit, mounting LED elements and components, and to ensure heat dissipation of a COB by maximizing contact area to a metal part where a COB mounts on.

### (Electrode Lands, Wiring)

The electrode lands 41 and 42 and the wirings 51 and 52 are formed as a pattern on the substrate 1 by screen printing or the like. A part of the wiring 51 and 52 may be a metal wire, which is used to connect between the LED elements or between the LED element and the wiring pattern. By wiring the LED elements using a metal wire without using the wiring pattern on the substrate 1, the light emission of the light emitting device can be enhanced by the high reflectance of the substrate on which the LED elements are mounted.

### (Led Element)

The LED element is appropriately selected from InGaN-based, GaAlAs-based, GaP-based and the like depending on the desired emission color. For general lighting, a white light is preferably emitted by using InGaN-based LED elements which present a peak emission wavelength in blue range (wavelength is 430 nm or more and 480 nm or less) or violet range (wavelength is 385 nm or more and 430 nm or less) and phosphors converting some or all of the light into other visible light color region. It is more preferably to use InGaN-based blue LED elements for reasons of luminous efficiency, availability, cost, etc.

The LED element arrays L1, L2 may be formed by different types of LED elements respectively, for example, the LED element array L1 may be composed of blue LED elements such as InGaN-based, the LED element array L2 may be composed of red LED elements such as GaAlAs-based. Further, different types of LED elements may be included in the LED element arrays L1, L2, for example, the LED element array L1 may be a combination of blue LED elements such as InGaN-based and red LED elements such as GaAlAs-based, or may be configured by a combination of InGaN-based LED elements having different wavelengths.

The LED element has an anode electrode pad and a cathode electrode pad and electrically connect with another LED element or the wiring pattern on the substrate via a metal wire. Or the LED element may be electrically connected with wiring pattern on the substrate through electrodes on the bottom side.

Either of the LED element arrays L1 and L2, which are connected in series, may be on the cathode side or the anode side of the light emitting device 100. The LED element arrays L1 and L2 may have a configuration in which a plurality of LED element arrays is connected in parallel, whereby the light emitting device 100 can operate at a large current.

A current at which the LED element array L1 starts light up in the light emitting device 100 may be adjusted by connecting other electronic components such as a diode on the LED element array L1 and changing current-voltage characteristics. When other components are connected, a threshold voltage of the LED element array is a value obtained by the sum of threshold voltages of the LED elements and threshold voltages of the other components.

### (Resin Dam)

The resin dam 3 is a resin for damming the translucent resin in the light emitting portion 2, and desirably absorbs little light, such as a transparent or white material.

### (Translucent Resin and Phosphor)

The LED elements are covered with a translucent resin, and the translucent resin selectively contains phosphors according to the desired emission color. Translucent resin is not limited as long as a resin having a translucent property. For example, a silicone resin with heat resistance is preferable. Translucent resin may be a resin having a different thixotropy in each light emitting region.

In the light emitting regions 21 and 22, some of the primary light emitted from the LED element is converted into light having spectra in the visible light by a phosphor. Preferably, the light from the blue LED element is converted into the light having a green to red spectrum by phosphors, and phosphor mixture ratio in each of the light emitting regions 21 and 22 is set to have desired light characteristics.

The translucent resin may not contain a phosphor, if the emission color from the LED element such as blue, green and red is used as the emission color of the light emitting region.

If the LED element arrays L1 and L2 have different types of LED elements and emit different colors, for example, the emission colors from the emitting portion 2 uniformly covered with a translucent resin can be different between when the LED element array L1 light up and when the LED element array L2 light up. In other words, the light emitting regions 21 and 22 in the light emitting portion 2 may not necessarily be distinguished by appearance.

A part of the LED element array may be covered with a translucent resin of same phosphor blend with another LED element array.

Emitting regions 21 and 22 may have a plurality of sub light emitting regions having different luminescent colors respectively. For example, light emitting region 21 may be composed of a plurality of sub light emitting region with different phosphor mixture ratio. The sub light emitting regions do not have to be in contact with each other.

### (Zener Diode)

As the Zener diode 7 keep a certain voltage at low current by the characteristics of breakdown voltage, the voltage of the light emitting device 100 can be maintained at a certain value even in low current region.

The Zener diode 7 is a generic term for diodes having a function of maintaining voltage at a certain value and includes a diode such as a transient voltage suppressor (TVS) diode.

In order to obtain desired voltage characteristics, a general diode such as rectifier diode may be connected in series with the bypass circuit 8 in the forward direction. When using a light emitting diode, it is necessary to consider the effect on the light emission color of the light emitting device. Further, desired voltage characteristics can be achieved without using a Zener diode by connecting multiple general diodes in series in the forward direction, although it is preferable to use a Zener diode as less diodes are required to achieve the desired voltage characteristics.

By using a Zener diode with a breakdown voltage higher than 5.1V with positive voltage-temperature characteristics, the voltage of the Zener diode 7 increases as the temperature of the light emitting device rises when operating in the rated current region. Thereby, the electric current which flows into the bypass circuit 8 is suppressed, and the luminous efficiency of a light emitting device can be improved. Thus, it is preferable that the Zener diode 7 is mounted and thermally connected on the same substrate on which the LED elements and the resistor 6 are mounted.

The Zener diode 7 may be implemented inside the resin forming the light emitting portion 2, and the substrate 1 can be downsized without requiring the mounting area in the outside of the light emitting portion 2. If the Zener diode 7 is an element type that is not packaged, it is easy to mount in the light emitting portion 2 by die bonding on the wiring pattern or by metal wires.

### (Resistor)

The resistor 6 is a resistance component, a printed resistor or the like. Besides resistance components, electric components having resistance such as inductors, thermistors or diodes may be used, and two or more parts may be combined to use.

Preferably, the resistor 6 is a thermistor having a positive temperature characteristic. The resistance of the thermistor increases to suppress a current flowing through the bypass circuit 8 and improve luminous efficiency of the light emitting device, when temperature of the light emitting device rises at rated current operation. It is preferable that the thermistor has a temperature characteristic having resistance rapidly increase at the range higher than room temperature and lower than actual temperature operated at rated current.

Since the resistance value of the resistor 6 affects the current at which the light emitting region 21 starts light up and the color change characteristics of the light emitting device 100, the accuracy is required. For example, 20% or less of accuracy is preferable.

Also, a printed resistor printed on a substrate is preferable, as it is possible to adjust the resistance in accurate by using such as laser trimming. Further, it is preferable to provide a terminal that can measure the resistance of the resistor 6 on the substrate 1.

Like the Zener diode, the resistor 6 may be implemented inside the resin forming the light emitting portion 2, and the substrate 1 can be downsized without requiring the mounting area in the outside of the light emitting portion 2.

### (Bypass Circuit)

The bypass circuit 8 is preferably formed on the same substrate on which the LED element array L1 is mounted.

The LED element arrays having the bypass circuits respectively may be connected in series inside the light emitting portion 2. The emission color change of the light emitting device 100 can be more finely controlled by each LED element arrays having different emission colors or luminous characteristics over current.

Also, every LED element array arranged in the light emitting portion 2 may be connected in parallel with different bypass circuit.

### Comparative Example

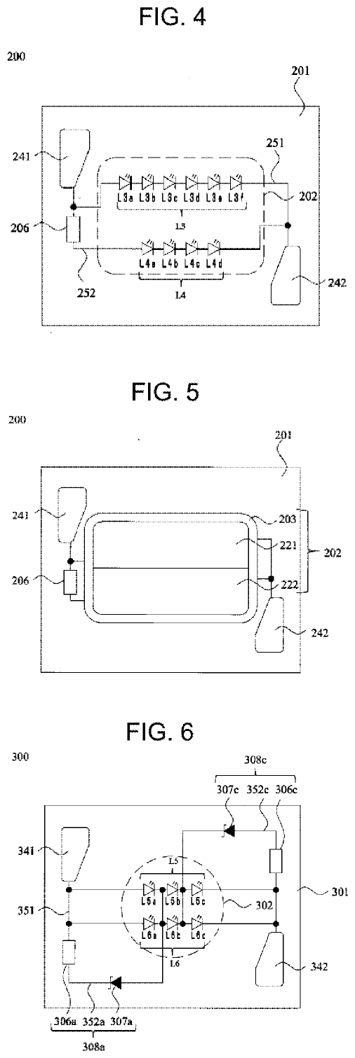

FIG. 4 is a wiring diagram of a light emitting device 200 according to the prior art disclosed in PTL 1. In order to obtain the same color change and the driving voltage as the first embodiment, a 6 series LED element array L3 and a 4 series LED element array L4 are connected in parallel between an electrode lands 241 and 242 by respective wires 251 and 252. A resistor 206 is connected to the LED element array L4, and when the driving voltage of the circuit on the wiring 252 varies depending on the current, the current shunted to the wirings 251 and 252 changes. Since the emission colors of the light emitting regions 221, 222 where LED element arrays L3, L4 are placed respectively in the light emitting portion 202 are different, the emission color from the light emitting portion 202 changes depending on the magnitude of the input current to the light emitting device 200.

In the light emitting device 100 of this embodiment, the minimum number of LED elements are six, while the number of LED elements in the light emitting device 200 is ten. That is, according to the present invention, the number of LED elements can be reduced to enable a smaller light emitting area.

Further, since the current flow only through the LED element array L4 of 4 series arrangement in the low current region, the driving voltage in the low current region is lower by 2 series of LED elements than the driving voltage in the rated current region where the current also flows through the LED element array L3 of 6 series arrangement. To reduce the threshold voltage difference between the LED element arrays while maintaining the current at which emission color starts to change, it is necessary to add an LED element in series to the LED element array L4 and reduce the resistance of the resistor 206. However, in this case, the light emission from the light emitting portion 202 is hard to achieve adequate color change, since the current to the LED element array L4 becomes larger and the current to the LED element array L3 becomes smaller in the rated current region.

### Embodiment 2

As shown in a wiring diagram of a light emitting device 300 of FIG. 6, a single light emitting portion 302 is formed on a substrate 301. An array L5 consisting from LED elements L5a˜L5c and an array L6 consisting from LED elements L6a˜L6c are placed inside the light emitting portion 302. The LED element arrays L5 and L6 are connected in parallel via the wiring 351 between the electrode lands 341 and 342. The LED elements L5a and L6a have a bypass circuit 308a in parallel having a resistor 306a and a Zener diode 307a on wiring 352a as in the first embodiment. The LED elements L5c and L6c also have a bypass circuit 308c in the same way.

In the present embodiment, since the bypass circuits 308a and 308c connect in parallel with a single series LED element, the Zener diodes 307a and 307c in the bypass circuit do not need to operate at high voltages and may be replaced by general diodes connected in the forward direction.

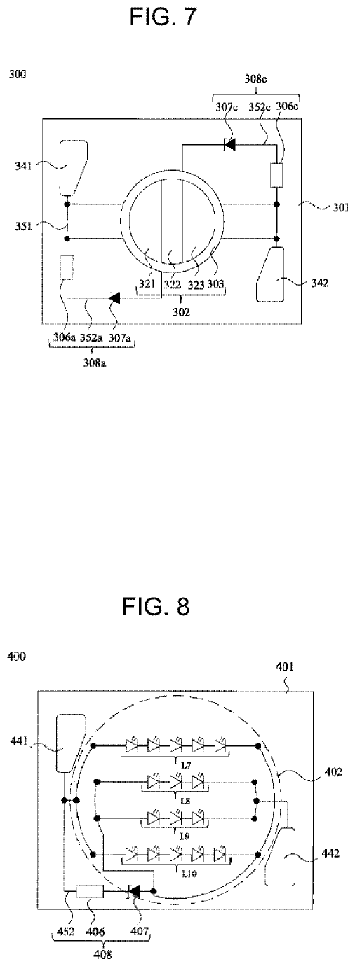

As shown in the plan view of FIG. 7, the light emitting portion 302 has a resin dam 303 on the periphery, consists from light emitting regions 321, 322 and 323 including LED elements L5a and L6a, L5b and L6b, L5c and L6c respectively, which are covered with the translucent resin. And each light emitting region 321, 322 and 323 emits specific luminous colors.

From the viewpoint of the relationship between the LED element arrays of the light emitting device 300 and the bypass circuits 308a and 308c, it is constituted by a series connection of three parallel connected groups of the LED elements L5a and L6a, L5b and L6b, L5c and L5c. Even the LED element array has one series configuration in the light emitting regions 321 and 323, light emission change according to the input current can be controlled by the bypass circuits 308a and 308c. Also, even when a low driving voltage is required for the light emitting device, the change of the emission color by the magnitude of the input current can be achieved. Further, since it can be constituted with a small number of the LED elements, it is easy to make the area of the light emitting portion 302 small.

Not limit to two parallel by the LED element arrays L5 and L6, parallel number of the LED element arrays may be arranged appropriately according to the rated current of the light emitting device 300. Thus, for example, one LED element array may be arranged when the rated current is small, or a three parallel more LED element arrays may be arranged when the rated current is large, and arrangement can be optimized depending on the current value.

By setting same emission color in the light emitting regions 321 and 323, and by making same configuration of the LED elements and bypass circuits 308a and 308c, light emission from the light emitting regions 321 and 323 changes in the same manner according to the current. More preferably, the light emitting regions 321 and 323 are formed symmetrically in the light emitting portion 302 and have two-line symmetrical emission color patterns with symmetry axis passing through the luminescent center from top view. With such an arrangement, it is easy to suppress color unevenness of the light emission from the light emitting device 300 by using optics or the like.

### Comparative Example

In order for a light emitting device to which the prior art is applied to have the similar emission color change and emission pattern as those of the present embodiment, a light emission region having at least three LED element arrays connected in parallel is necessary in the light emitting portion. As the light emitting region adjacent each other emit different emission color, each of the light emitting region is required to be wider than the width of LED element array. Thus, if the light emitting portion is the limited size in which only two LED element allay can be placed in parallel as shown in FIG. 6, the prior art is difficult to apply.

Furthermore, in order to perform a large current operation of the light emitting device by the prior art, it is usually necessary to increase the number of LED elements connected in parallel for both the low voltage LED element array and the high voltage LED element. While, the present invention cope with large current operation in the limited area of the light emitting portion, since number of elements connected in parallel can be optimized depending on total current.

### Embodiment 3

As shown in a wiring diagram of a light emitting device 400 of FIG. 8, a single light emitting portion 402 is formed on a substrate 401, LED device arrays L7, L8, L9 and L10 are disposed inside the light emitting portion 402, the LED element arrays L7 and L10 with the same series number of LED elements are connected in parallel, the LED element arrays L8 and L9 with the same series number of LED elements are connected in parallel, the LED element arrays L7 and L10 are electrically connected with the LED element arrays L8 and L9 in series between electrode lands 441 and 442. The LED element arrays L7 and L10 are connected in parallel with a bypass circuit 408 having a resistor 406 and a Zener diode 407 on wiring 452 as in the first embodiment.

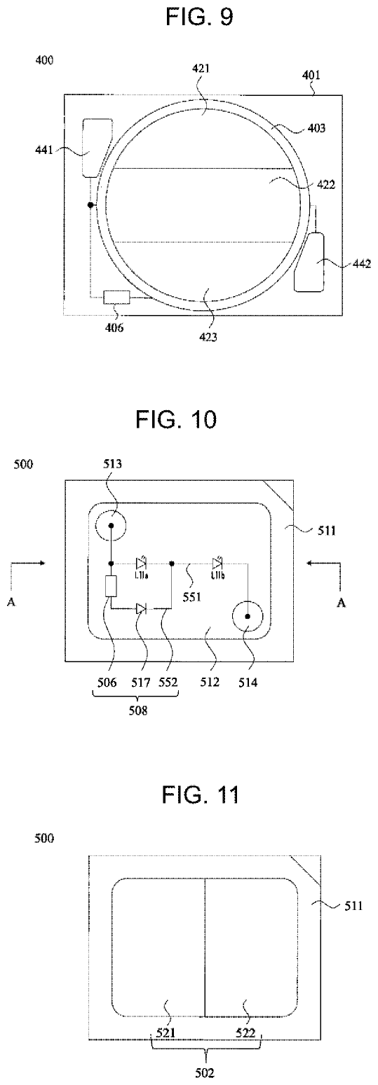

As shown in a plan view of FIG. 9, the light emitting portion 402 has a resin dam 403 on the periphery, consists from a light emitting region 421 having the LED element array L7, a light emitting region 422 having the LED element arrays L8, L9 and a light emitting region 423 having the LED element array L10, covered with a translucent resin. And each light emitting region emits specific luminous color.

The light emitting regions 421 and 423 are preferably formed symmetrically with respect to the emission center in the light emitting portion 402 and emit same emission color, so that emission color pattern has two-line symmetrical axis passing through the luminescent center from top view. Thus, it becomes easy to suppress color unevenness of light emitted from the light emitting device 400 by using optics or the like. As emitting regions 421 and 423 share bypass circuit 408, it is easy to obtain the same light emission change characteristics over current.

By arranging LED elements of the LED element arrays L8 and L9 near the center of the light emitting portion 402, the light from the center of the light emitting region 402 becomes dominant in the light emitting portion 422, and the emission from the periphery is reduced. Thus, color unevenness when the light emitting device 400 is viewed from the lateral direction can be suppressed.

By increasing series number of LED elements in each LED element arrays, the driving voltage of the light emitting device 400 can be higher.

### Comparative Example

In the prior art, since LED element arrays in emitting regions of different emission colors connect in parallel, series number of each LED element arrays needs to be increased in order to get higher driving voltage of the light emitting device. For this reason, when the area of the light emitting portion is limited, it becomes difficult to set the driving voltage of the light emitting device high. On the other hand, in the present invention, LED element arrays in different emitting region are connected in series, it is easy to increase the driving voltage of the light emitting device even if the area of the light emitting portion is limited.

### Embodiment 4

As shown in a wiring diagram of FIG. 10, a light emitting device 500 has a mounting portion 512 in a surface mounting type package 511, LED elements Lila and L11b are disposed in the mounting portion 512. A bypass circuit 508 for the LED element Lila is formed by wiring 552, a resistance 506 and a diode 517.

As the mounting area of a surface mounting type package is generally limited, a required mounting area may be reduced by placing either of the LED element L11a, the diode 517 and the resistor 506 on top of one another. The wiring 551 and 552 are formed by a wiring pattern on the mounting surface or by metal wire. As the mounting area of a surface mounting type package is generally limited, it is preferable a metal wire to be used.

The diode 517 on the bypass circuit 508 may be a Zener diode with breakdown voltage is lower than the threshold voltage of the LED element Lila.

LED elements Lila and L11b may be LED element arrays composed of a plurality of LED elements connected in series, or may be a plurality of LED elements connected in parallel.

The surface mounting type package 511 is made by resin or ceramic as a material and has electrode terminals on the back, which connect with the wiring electrode lands 513 and 514 provided in the mounting portion by a metal frame, a metal through-hole or the like.

As shown in a plan view of FIG. 11, the mounting portion is covered with translucent resin to form a light emitting portion 502, and the light emitting portion 502 is composed of light emitting regions 521 and 522 having different emission colors. Light emission from the package 511 is a mixed color from the light emitting regions 521 and 522.

By adopting LED elements Lila and L11b having different emission colors, it is possible to obtain a light emitting device 500 that emits different light emission color according to the input current simply by sealing with same translucent resin. In this case, the light emitting portion 502 may be sealed by the translucent resin with same phosphor blend.

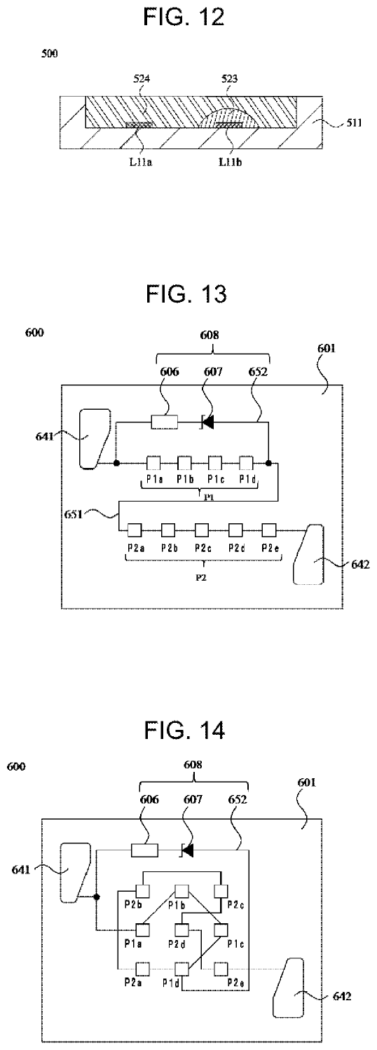

Further, even if the light emitting colors of the LED elements Lila and L11b are the same, the light emitting device 500 that emits different light emission colors according to the input current is obtained by covering the respective LED elements using translucent resin with different phosphor blend. Light emitting regions having different emission colors can be formed by resin molding in a specific region such as making a partition wall between the LED elements 11a and 11b or using a high thixotropic translucent resin for one LED element. As shown in A-A cross-sectional view of FIG. 12, one LED element L11b may be sealed at lower height from the surface of the package by the translucent resin 523 with phosphor blend mixed for lower color temperature emission. Then, the whole package may be sealed by the translucent resin 524 with phosphor blend mixed for higher color temperature emission.

### Embodiment 5

As shown in a wiring diagram of a light emitting device 600 of FIG. 13, LED packages P1a˜P1d and P2a˜P2e are mounted and electrically connected in series on a substrate 601 which has electrode lands 641, 642 and wiring pattern, and LED package arrays P1 and P2 are formed. The LED package array P1 connects with a bypass circuit 608 in parallel comprising a resistor 600 and a Zener diode 607. By connecting multiple LED packages, internal LED elements are also connected to each other, thus each LED package array is electrically equivalent to an LED element array.

The LED packages P1a˜P1d and P2a˜P2e are mounted on a single substrate. Preferably by being arranged in a small distance from each other, a single light emitting source is formed. Small and high-power surface mount packages or chip-scale packages are preferably used as LED packages because a single light source can be easily formed.

By using LED package arrays P1 and P2 having different emission colors and appropriately selecting the resistor 606 and the Zener diode 607 in the bypass circuit as in the previous embodiment, an emission color change by the magnitude of the current can be realized.

LED packages belonging to the same LED package array are preferably constituted by LED packages of same emission color, and desired emission color is easily obtained.

As shown in a variation example of FIG. 14, it is preferable that LED package belonging to different LED package array adjoin each other and each emission color pattern is symmetrically arranged from the center of the light to achieve better color mixing properties as a single light source.

The present invention is not limited to the embodiments described above, and various modifications are possible within the scope of the claims, embodiments obtained by appropriately combining technical means disclosed in different embodiments also included in the technical scope of the present invention.

### Example 1

In Example 1, a test was performed using the light emitting device of the same configuration as that of the first embodiment.

The substrate 1 was alumina ceramic, the resistor 6 was 33 ohms, and the breakdown voltage of the Zener diode 7 was 7.5V. The LED elements were InGaN-based blue light emission elements, and there were LED element arrays L1 with 4 elements series and L2 with 2 elements series, and they were connected in series with each other. The LED element array L1 with 4 elements series and the bypass circuit 8 were connected in parallel. The threshold voltage of the LED element array L1 with 4 elements series was approximately 10.4 V. Each LED element array was sealed by a silicone resin with phosphor, the 4 elements series array emitted white light of a color temperature 4000K, the 2 elements series array emitted incandescent light color of a color temperature 2800 K.

Next, the changes in color temperature of the light emission from the entire light emitting device and voltage were examined with respect to the input current.

When a forward current was 30 mA, emission color from the light emitting device was 2800 K and a forward voltage was 13.9V. When a forward current was 350 mA, emission color from the light emitting device was 3500K and a forward voltage was 17.7V.

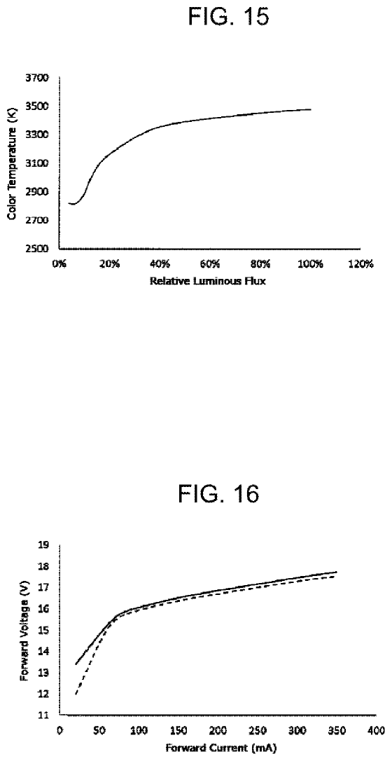

FIG. 15 is a graph showing changes in color temperature of light emission with respect to the relative luminous flux of the light emitting device. It can be seen that the color temperature of the light emission decreased as the relative luminous flux decreases.

FIG. 16 is a graph showing changes in voltage with respect to the forward current. For comparison, changes in voltage are shown by broken line for the light emitting device of the same configuration as that of the light emitting device 200 according to the prior art. The LED elements were InGaN-based blue light emission elements, and there were LED element arrays L3 with 6 elements series and L4 with 4 elements series, connected in parallel with each other. The resistor 206 connected to the LED element array L4 was 50 ohm.

In the light emitting device according to the invention, voltage drop in the low current region was particularly suppressed, and it can be seen that the voltage difference between the low current region and the rated current region was smaller.

1. A light emitting device comprising:
a first LED element array and a second LED element array, each of which has one or more LED elements,
wherein the first LED element array and the second LED element array are connected in series,
at least one of which is connected in parallel with a bypass circuit having a resistor and a diode connected in series,
a threshold voltage of the LED element array connected in parallel with the bypass circuit is higher than a threshold voltage of the diode, and
an emission color by emission of the first LED element array is different from an emission color by the emission of the second LED element array.

2. The light emitting device according to claim 1, wherein the first LED element array, the second LED element array and the bypass circuit are formed on a single substrate.

3. The light emitting device according to claim 1, wherein a difference of color temperature between the emission color generated by emission of the first LED element array and the emission color generated by emission of the second LED element array is equal to or larger than 1000 K.

4. The light emitting device according to claim 1, wherein the diode is a Zener diode.

5. The light emitting device according to claim 1, wherein the light emitting region which emits light of each LED device array is formed to have two or more axes of symmetry passing through the emission center from top view.
